(19) United States
(12) Patent Application Publication
(10) Pub. No.: US 2011/0237065 A1
(43) Pub. Date: Sep. 29, 2011

(54) SOLDERING FLUX AND METHOD FOR MANUFACTURING A SEMICONDUCTOR DEVICE USING THE SAME

(75) Inventor: Fumiyoshi KAWASHIRO, Kanagawa (JP)

(73) Assignee: RENESAS ELECTRONICS CORPORATION

(21) Appl. No.: 13/053,958

(22) Filed: Mar. 22, 2011

(30) Foreign Application Priority Data
Mar. 24, 2010 (JP) 2010-068771

(51) Int. Cl. H01L 21/44; B23K 35/34

(52) U.S. Cl. 438/615; 148/23; 257/E21.476

(57) ABSTRACT

Soldering flux includes: a solvent of which solubility in water is more than 0.01% by weight and less than 6.8% by weight; an organic acid component; and amine counteracting the organic acid component. A solubility of the amine in water is more than 5.0% by weight, and the amine is able to be linked to a conductive metal via a coordination linkage. A solder bump is formed by heating a solder ball with the soldering flux. The residue of the flux on the surface of the solder bump has water solubility, and is easily eliminated. Further, the conductive metal coordinated to the amine is deposited on the surface of the solder bump by water washing. As a result, when testing the semiconductor device having the solder bump 7 by a contact pin contacting with the solder bump, the contact pin is prevented from contamination, the contact pin is certainly contacted with the solder bump, and the semiconductor device is accurately tested.

### INCORPORATION BY REFERENCE

This patent application claims a priority on convention based on Japanese Patent Application No. 2010-068771. The disclosure thereof is incorporated herein by reference.

### BACKGROUND OF THE INVENTION

1. Field of the Invention

The present invention relates to soldering flux and a method of manufacturing a semiconductor device using the same.

2. Description of Related Art

In a wiring board on which a semiconductor element or an electronic component is mounted, BGA (Ball Grid Array) mounting is frequently employed in which solder balls are connected to electrodes of the wiring board. In this BGA mounting, the solder balls and the electrodes on the wiring substrate are heated, the solder balls are melted and jointed to the electrodes in a reflow step, and thereby solder bumps are formed.

A technique for improving mechanical and electrical reliability of a solder bump is disclosed in Patent Literature 1 (Japanese patent publication JP2004-154845A) and Patent Literature 2 (Japanese patent publication JP2001-114747A).

Patent literature 1 discloses lead-free solder for connecting electric devices is disclosed, wherein growth of intermetallic compounds is suppressed at a boundary with a package metalized by Cu or a terminal surface of a printed board, and a problem of a defect caused by a boundary fracture related to crushproof is solved. The solder for connection of the electronic devices is characterized by including mainly tin (Sn) and containing silver (Ag) of at most 5.0 mass %, copper (Cu) of at most 1.0 mass %, and elements segregating in grain boundaries of 0.008-0.10 mass %.

Further, Patent Literature 2 discloses soldering flux for forming the solder bumps. This soldering flux is water soluble soldering flux characterized by containing a compound as an activator obtained by reacting dicyandiamide with glycidol in order not to affect insulation reliability even though the soldering flux remains in an electrical device.

### SUMMARY

As a result of studying by the present inventor, it was found out that there is a case where the soldering flux remains on the solder bumps of the semiconductor device, contact failure is occurred between the solder bumps and contact pins of a test device, and the electrical test was not correctly carried out. The below description is based on the result of the study by the present inventor.

FIG. 1 shows a solder bump part of a semiconductor device 110. FIG. 1 is a magnified view showing region A shown in FIG. 12. As shown in FIG. 12, a semiconductor chip 150 is mounted on a wiring substrate 1, a circuit (not shown) of the semiconductor chip 150 is connected to a wiring (not shown) of the wiring substrate 1 via bonding wires 160. The wiring of the wiring substrate 1 is connected to an electrode 2 shown in FIG. 1. Solder resist 3 having an opening portion is formed on the wiring substrate 1, and the electrode 2 is formed in the opening portion. A solder ball (not shown) is heated to be connected to the electrode 2 in a reflow process, and thereby the solder bump 107 shown in FIG. 1 is formed. Here, soldering flux is used in order to secure the connection between the electrode 2 and the solder ball. By using the soldering flux, the electrode 2 and the solder ball are securely connected in the reflow process. After the solder ball is connected to the electrode 2, the soldering flux is removed by washing.

After the solder bump 107 is formed, the electrical test is carried out to confirm whether or not the semiconductor device 110 is normally operated. The electrical test is carried out by contacting a contact pin 11 of a test device to the solder bump 107.

Herein, there was a case where the semiconductor device 110 was not electrically operated when the electrical test was carried out by the contact pin 11 even though there was no problem in electrical connection between the solder bump 107 and the semiconductor chip 150.

A surface of the solder bump 107 was analyzed, and it was found that a thin layer 123 (hereinafter, referred to as high resistance layer 123), which included an insulating poly-silicon compound and a residue of the soldering flux or the like, was formed on the surface of the solder bump 107 as shown in FIG. 2, and this layer 123 prevented electrical connection between the solder bump 107 and the contact pin 11. FIG. 2 is a pattern diagram showing a neighborhood of a surface of the solder bump 107.

It was found that the surface of the solder bump 107 has a structure including an oxidation product layer 22 (about 4 nm) and the high resistance layer 123 (about 2 nm) which are laminated in order on a base material 21 having a main component of tin (Sn). The oxidation product layer 22 included a first oxidation product layer 24 and a second oxidation product layer 24. The first oxidation layer 24 was a layer in which a compound formed of Sn, phosphorus (P), and oxygen (O) was incrassated, and the first oxidation layer 24 was formed of a material in which the compound was blended into alloy composing the base material 21. As the compound, phosphate of Sn is exemplified. The second oxidation layer 25 was a layer having a concentrated metallic oxide and was formed of a substance of tin oxide (SnOₓ) mixed with tin (Sn). The high resistance layer 123 was formed of insulating soldering flux remaining without removal after washing of the solder bump 107 after forming the solder bump 107, and insulating poly-silicon compound or the like. The poly-silicon compound was poly dimethyl siloxane (PDMS) and the like, and had been contained in the solder resist 3, and a minute amount thereof had melted into the soldering flux and had remained on the surface of the solder bump 107 together with the soldering flux.

The high resistance layer 123 prevents electrical connection between the solder bump 107 and the contact pin 11, and is also stripped to adhere and deposit on the contact pin 11 during the electrical test. If such contact pin 11 is continuously used for the electrical test, the electrical contact between the solder bump 107 and contact pin 11 is prevented, and therefore the electrical test of the semiconductor device 110 cannot be performed accurately.

The soldering flux according to the present invention includes: a solvent of which solubility in water is more than 0.01% by weight and less than 2.8% by weight; an organic acid; and an amine counteracting the organic acid. The solubility of the amine in water is more than 5% by weight. The amine can be linked to a conducting metal via coordination linkage.

According to an aspect of the present invention, when a solder bump is formed by heating a solder ball on which the soldering flux is applied, since the soldering flux has water solubility, the soldering flux can be easily eliminated by water washing. Furthermore, in the water washing, the conducting metal to which the amine is bonded via coordination linkage can be educed on a surface of the solder bump. Accordingly, when testing the semiconductor device having the solder bump with using a contact pin, the contact pin can be prevented from being contaminated by insulating material, and the contact pin can be certainly contacted with the solder bump. As a result, it becomes possible to correctly test the semiconductor device.

The method of manufacturing a semiconductor device according to another aspect of the present invention includes: forming a solder bump by heating a solder ball with soldering flux; and washing the solder bump by water. The soldering flux includes: a solvent of which solubility in water is more than 0.01% by weight and less than 6.8% by weight; an organic acid; and an amine counteracting the organic acid. The solubility of the amine in water is more than 5% by weight. The amine can be bonded to a conducting metal via coordination linkage.

According to the aspect of the present invention, since the soldering flux covering a surface of the solder bump has water solubility, the soldering flux can be easily eliminated by water washing. Additionally, in water washing, the conducting metal to which the amine is bonded via coordination linkage can be educed on the surface of the solder bump. Accordingly, when testing the semiconductor device having the solder bump with using a contact pin, the contact pin can be prevented from being contaminated by insulating material, and the contact pin can be certainly contacted with the solder bump. As a result, it becomes possible to correctly test the semiconductor device.

According to the aspect of the present invention, soldering flux and a method of manufacturing a semiconductor device with the same are provided, in which a test for a semiconductor device can be correctly carried out by using a contact pin contacted to a solder bump.

### BRIEF DESCRIPTION OF DRAWINGS

The above and other objects, advantages and features of the present invention will be more apparent from the following description of certain preferred embodiments taken in conjunction with the accompanying drawings, in which:

FIG. 1 is a section view in a vicinity of a solder bump showing a testing method of a semiconductor device for explaining an object of the present invention;

FIG. 2 is a schematic diagram in the vicinity of the solder bump surface for explaining the object of the present invention;

FIG. 3 is a section view in the vicinity of the solder bump of a semiconductor device after soldering flux of the present invention is applied;

FIG. 4 is a section view in the vicinity of the solder bump of the semiconductor device after the solder ball is mounted;

FIG. 5 is a section view showing the vicinity of the solder bump of the semiconductor device after the solder ball is heated;

FIG. 6 is a section view showing the vicinity of the solder bump of the semiconductor device after the solder ball is washed by water;

FIG. 7 is a diagram showing a contact pin used for testing the semiconductor device;

FIG. 8 is a table showing properties of materials applied to a solvent;

FIG. 9 is a schematic diagram showing the vicinity of the surface of the solder bump after water washing;

FIG. 10 is a graph showing a relationship between a ratio of a number of Cu atoms to a number of Sn atoms at the surface of the solder bump and an yield rate of the semiconductor device;

FIG. 11 is a graph showing a relationship between a ratio of a number of Cu atoms to Sn in the solder bump surface and an yield rate at a retest of the semiconductor device; and

FIG. 12 is a section view showing the semiconductor device.

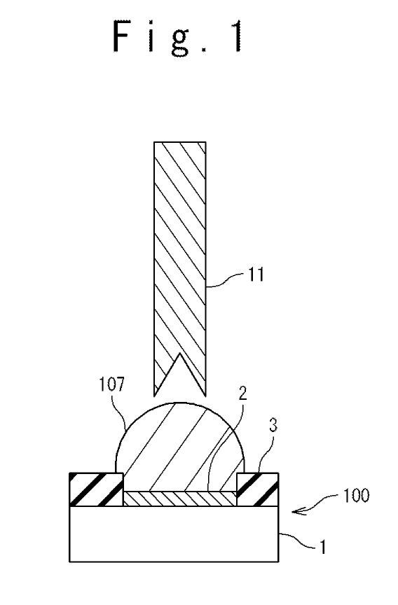

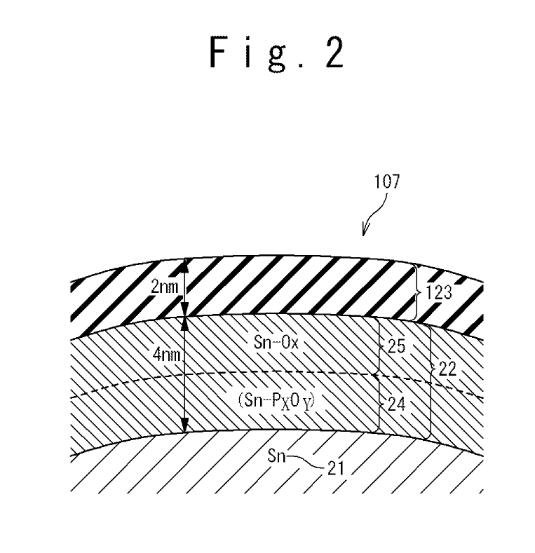

### DESCRIPTION OF THE PREFERRED EMBODIMENTS

Referring to drawings, an embodiment according to the present invention will be explained below.

At first, soldering flux 5 according to the present invention will be explained. The soldering flux 5 includes a solvent, an organic acid, and an amine. If necessary, a bodying agent and a surface acting agent may be included.

A boiling point of the solvent of the soldering flux 5 is more than a melting temperature of solder at which the solder ball 6 is melted, and a solubility of the solvent in water is more than 0.01% by weight and less than 6.8% by weight.

Since the solubility in water is set to be less than 6.8% by weight, an affinity between the solvent and an organic material is enhanced, and the organic material adhering on surfaces of an electrode 2, a solder ball 6, and a solder bump 7 can be dissolved and removed. On the other hand, since the solubility in water is set to be more than 0.01% by weight, the solvent can be blended into water. Thus, the soldering flux 5 can be removed by water washing.

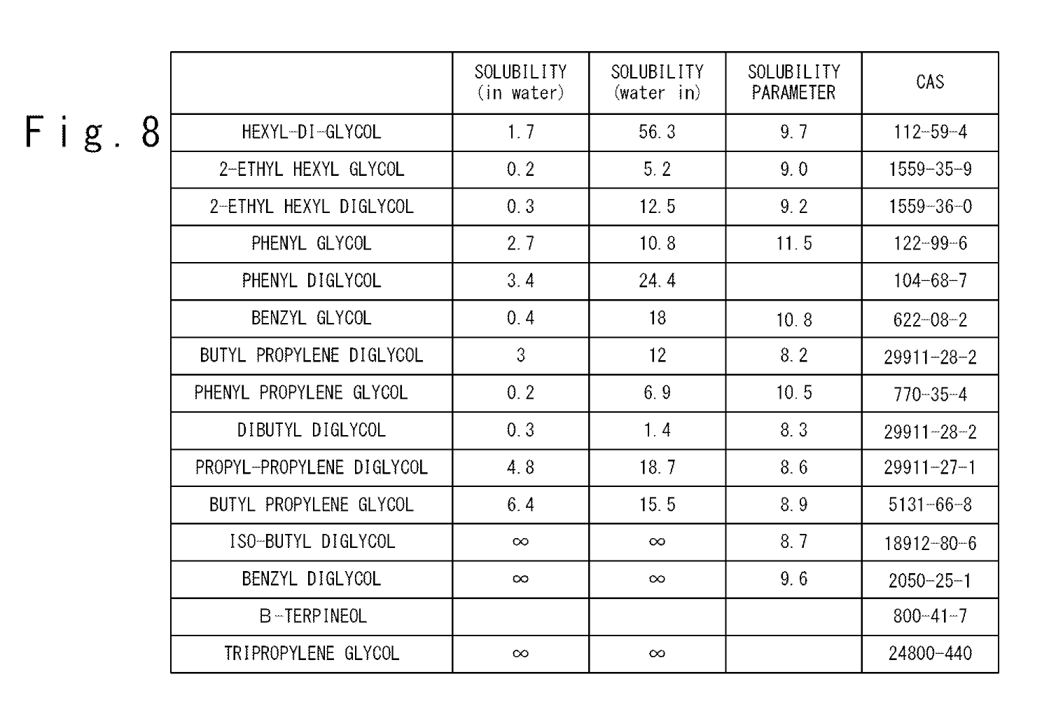

As the solvent, as shown in FIG. 8, hexyl glycol, 2-ethyl hexyl glycol, 2-ethyl hexyl diglycol, phenyl glycol, phenyl diglycol, benzyl glycol, butyl propylene diglycol, phenyl propylene glycol, dibutyl diglycol, propyl-propylene diglycol and butyl propylene glycol are illustrated.

As the organic material adhered to surfaces of the electrode 2, solder ball 6 and solder bump 7, organic compounds such as organic silicon, acrylic, epoxy and the like contained in the solder resist 3 are exemplified. In order to eliminate these organic compounds, the solubility in water is preferably lower than 5.0% by weight. Accordingly, it is preferable to use the solvent of which solubility in water is 0.01% by weight to 5.0% by weight. As such solvent, hexyl glycol, 2-ethyl hexyl glycol, 2-ethyl hexyl diglycol, phenyl glycol, phenyl diglycol, benzyl glycol, butyl propylene diglycol, phenyl propylene glycol, dibutyl diglycol and propyl-propylene diglycol are exemplified.

A contained amount of the solvent in the soldering flux 5 is 39% to 69% by weight.

The amine in the soldering flux 5 includes multidentate ligand that has a plurality of group coordinating with one metal atom (conductive metal atom). Here, the conductive metal atom is Cu, Ni, Au or Ag. As the amine, a material is illustrated in which ethylene-diamine, poly-oxy ethylene-diamine or derivatives thereof is linked to Cu, Ni, Au, or Ag and the like via a coordination linkage. Moreover, cyclic hydrocarbon or water-soluble polyamine resin may be added in the amine.

As to the amine in the soldering flux 5, it is only necessary that the conductive metal such as Cu, Ni, Au or Ag can be once coordinate-bonded and dissolved, and it is not necessarily that the conductive metal is initially coordinate-bonded to amine in of soldering flux 5. That is to say, when the soldering flux 5 is contacted to the solder ball 6 and the electrode 2, the conductive metal included in the solder ball 6 or the electrode 2 may be linked to the amine via the coordination linkage.

Furthermore, the solubility of the amine in water is preferably set to be more than 5% by weight such that the solubility in water of the soldering flux 5 is maintained. Moreover, since the soldering flux 5 is used at the time of melting the solder, a boiling point of the amine is preferably more than the melting point of the solder. Specifically, the boiling point of the amine is preferably more than 250° C.

As the amine satisfying these conditions, Ethoduomeen, Jeffamine and Poloxamine are exemplified. The CAS number of Ethoduomeen is 61790-85-0. The CAS number of Jeffamine is 65605-36-9. The CAS number of Poloxamine is 11111-34-5. A contained amount of the amine is more than 30% by weight and less than 60% by weight.

The organic acid in the soldering flux 5 has a plurality of organic acid group in one molecule in order to increase activity per a mol. As the organic acid group, a carboxyl group is exemplified. The organic acid is used for dissolving an oxide film on the metal surface (electrode 2 etc.) so as to facilitate the solder to be attached onto the metal surface. By the organic acid, a below chemical reaction is proceeded such that the oxide film is removed.

2RCOOH+Cu₂O→2RCOOCu+H₂O

In order to promote the above chemical reaction for removing the oxide film by pre-heating in a reflow process, the melting point of the organic acid is preferably more than 145° C. Furthermore, in order to increase the melting point, in a position excluding the carboxyl group, hydrogen atoms may be replaced by other substituent groups. A contained amount of the organic acid in the soldering flux 5 is more than 1% by weight and less than 20% by weight.

As the organic acid, diglycolic acid O(CH₂COOH)₂, adipic acid HCOOH(CH₂)₄COOH, dimethylol-propionic acid C₅H₁₀O₄, succinic acid C₄H₆O₄ and citric acid C₆H₈O₇ are exemplified. The CAS number of diglycolic acid O(CH₂COOH)₂ is 110-99-6. The CAS number of adipic acid HCOOH(CH₂)₄COOH is 124-04-9. The CAS number of dimethylol-propionic acid C₅H₁₀O₄ is 4767-03-7. The CAS number of succinic acid C₄H₆O₄ is 110-15-6. The CAS number of citric acid C₆H_{B}O₇ is 77-92-9.

A bodying agent may be included in the soldering flux 5, in order to set up viscosity of a mixture of the solvent, the organic acid and the amine. It is noted that when the mixture has desired viscosity, the bodying agent is not necessary to be included, and addition of the bodying agent may be omitted.

The surface acting agent may be included in the soldering flux 5 such that the solvent, the organic acid and the amine are sufficiently mixed, but addition of the surface acting agent may be omitted.

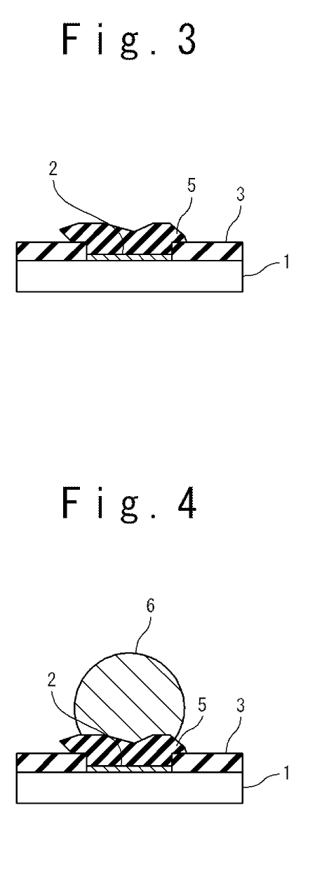

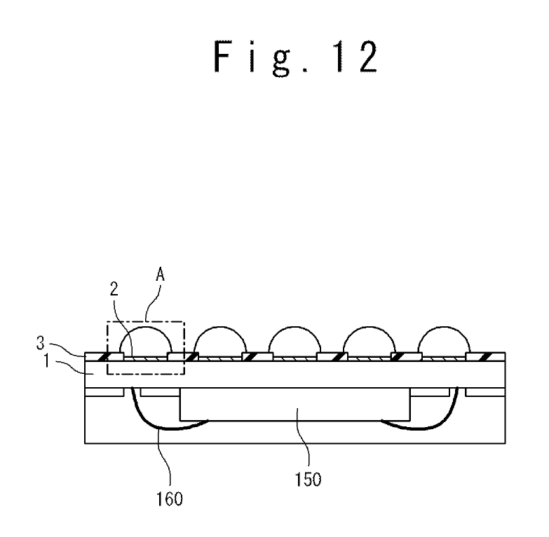

Next, with reference to FIGS. 3 to 7, a method of manufacturing a semiconductor device 10 with using the soldering flux 5 of the present invention will be explained. FIGS. 3 to 7 are magnified diagrams each showing a vicinity of a solder bump 7 of the semiconductor device 10. These diagrams are magnified diagrams showing a region A shown in FIG. 12. As shown in FIG. 12, a plurality of solder bumps 7 are formed by the manufacturing method shown in FIG. 3 to 7.

Initially, as shown in FIG. 12, a wiring board 1 on which a semiconductor chip 150 is mounted is prepared. A plurality of electrode 2 are formed on a surface of the wiring board 1, a solder resist 3 is formed on the surface of the wiring board, and the solder resist 3 has opening portions such that each electrode 2 is exposed. The solder resist 3 is composed of a material that is hard to be wet with the solder, and includes organic materials exemplified as an organic silicon compound (for example, siloxane), an acrylic compound, and an epoxy compound. The electrode 2 includes a metal such as Cu. The electrode 2 is electrically connected to an electric circuit (not shown) in the semiconductor chip 150, via a circuit of the wiring board 1 and bonding wires 160.

Next, as shown in FIG. 3, the soldering flux 5 is applied on the plurality of the electrodes 2. The soldering flux 5 may be applied by squeegee printing method, a sealed-type pressure printing method, or other methods.

After the soldering flux 5 is applied, as shown in FIG. 4, a plurality of solder ball 6 are mounted on the wiring board 1. The plurality of solder ball 6 are arranged on the wiring board 1 such that each solder ball 6 is contacted with the soldering flux 5.

At this time, the solder ball 6 or the electrode 2 may be partially dissolved into the soldering flux 5 to be linked to the amine in the soldering flux 5 via a coordination linkage. If the soldering flux 5 includes the amine that is not bonded to the metal by coordination linkage, the amine is coordinate-bonded with the metal for the first time in this process. Specifically, this metal is Cu, Ag, Au, Ni or the like included in the electrode 2 and the solder ball 6.

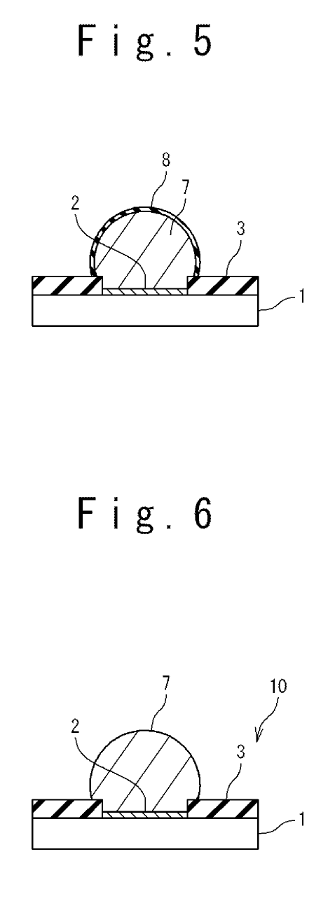

The wiring board 1 is heated at reflow process, after the plurality of solder ball 6 are mounted. By this heating, the soldering flux 5 covers the surfaces of the solder ball 6 and the electrode 2, and the solder ball 6 is melted to form a solder bump 7. After the solder bump 7 is formed, as shown in FIG. 5, a flux layer 8 including the soldering flux 5 is formed on the surface of the solder bump 7.

The flux layer 8 includes the soldering flux 5, a component included in the solder resist 3, and a material originating from a contamination component that covers each of the electrode 2 and soldering ball 6. As the material included in the flux layer 8, an oxide silicon compound R—SOₓ, a poly-dimethyl siloxane compound, an acrylic compound, and an epoxy compound or the like are exemplified.

After that, the solder bump 7 is washed by water, the flux layer 8 is removed, and the semiconductor device 10 is obtained as shown in FIG. 6.

According to the present invention, since the soldering flux 5 includes the solvent having a solubility in water of 0.01% by weight or more and the amine having a solubility in water of 5% by weight or more, the soldering flux 5 can be removed by water washing. At this water washing process, the coordination linkage between the conductive metal and an amine ligand is cut off, the amine ligand is removed, and the conductive metal is deposited.

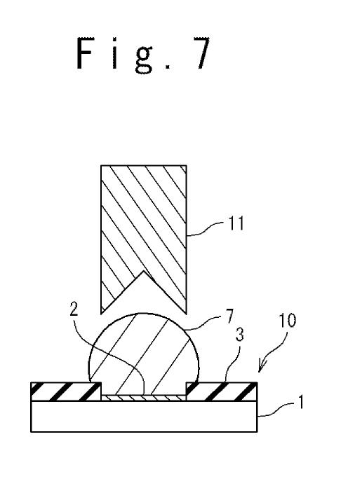

After the water washing, an electrical test of the semiconductor device 10 is carried out by a testing device. As shown in FIG. 7, a contact pin 11 formed by a conductor is provided in the testing device, and the electrical test is carried out by directly contacting the contact pin 11 with the soldering bump 7. Though there is not shown in FIG. 7, the testing device has a plurality of contact pin 11 each of which corresponds to the each solder bump 7.

Subsequently, the semiconductor device 10 will be explained, which is obtained by using the soldering flux 5 according to the present invention.

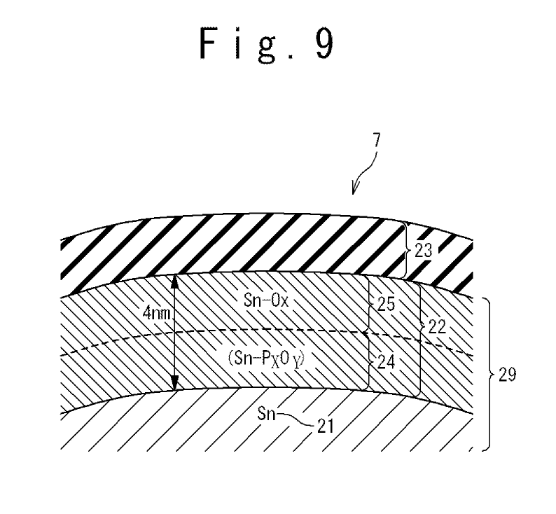

FIG. 9 is a pattern diagram showing the vicinity of the surface of the solder bump 7 of the semiconductor device 10 shown in FIG. 6 manufactured by the manufacturing method mentioned above.

The solder bump 7 includes a base part 29, and a surface part 23 that covers the base part 29. A thickness of the surface part 23 is about 2 nm to 6 nm. The base part 29 includes a base material 21 and an oxidation products layer 22 that covers the surface of the base material 21.

The surface part 23 includes Sn and conductive metal. The conductive metal is Cu, Ni, Au, or Ag and the like supplied from the amine included in the soldering flux 5. Since Cu, Ni, Au, or Ag or the like is linked to the amine included in the soldering flux 5 via the coordination linkage, the amine ligand is removed by the water washing, and Cu, Ni, Au, or Ag or the like is deposited. The surface part 23 is formed of these conductive metals. As to a part of Cu, Ni, Au, or Ag or the like, the coordinate-bonding with the amine may be partly remained.

When using the soldering flux 5 according to the present invention, in a unit volume of the surface part 23, a ratio of a number of conductive metal atoms to a number of Sn atoms is larger than 0.01. By increasing the contained amount of the amine in the soldering flux 5, the ratio can be larger than 0.015. This ratio can be quantitatively evaluated by TOF-SIMS (Time-of-Flight Secondary Ion Mass Spectroscopy).

In the soldering flux 5 according to the present invention, since the solubility of solvent in water is limited, an affinity with organic materials can be increased, insulating materials such as a poly-silicon compound or an organic insulating material included in the surface part 23 can be effectively removed, and an contained amount of the insulating material in the surface part 23 can be reduced. Here, as the insulating material, poly-dimethyl siloxane (PDMS) or the like is illustrated, and the insulating material includes Si and C. As shown in FIG. 9, when using the soldering flux 5 according to the present invention, contained amounts of Si and C in the surface part 23 can be decreased such that the ratio of a number of Si or C atoms to a number of Sn atoms per a nut volume can be smaller than 0.01, and it can be understood that the insulating material can be effectively removed from the surface of the solder bump 7. This is because the solubility in water of the solvent of the soldering flux 5 is set to be less than 6.8% by weight, in particular, less than 5.0% by weight, and the affinity with the organic materials is increased such that the poly-silicon compound and the organic insulating material can be removed from the surface of the solder bump 7.

The oxidative products layer 22 is about 4 nm in thickness, and includes a first oxidative products layer 24 and a second oxidative products layer 25 in this order from the side of the base material. The first oxidative products layer 24 is mainly composed of tin phosphate SnPₓO_{y}. The second oxidative products layer 25 covering the first oxidative products layer 24 is mainly composed of tin oxide SnOx.

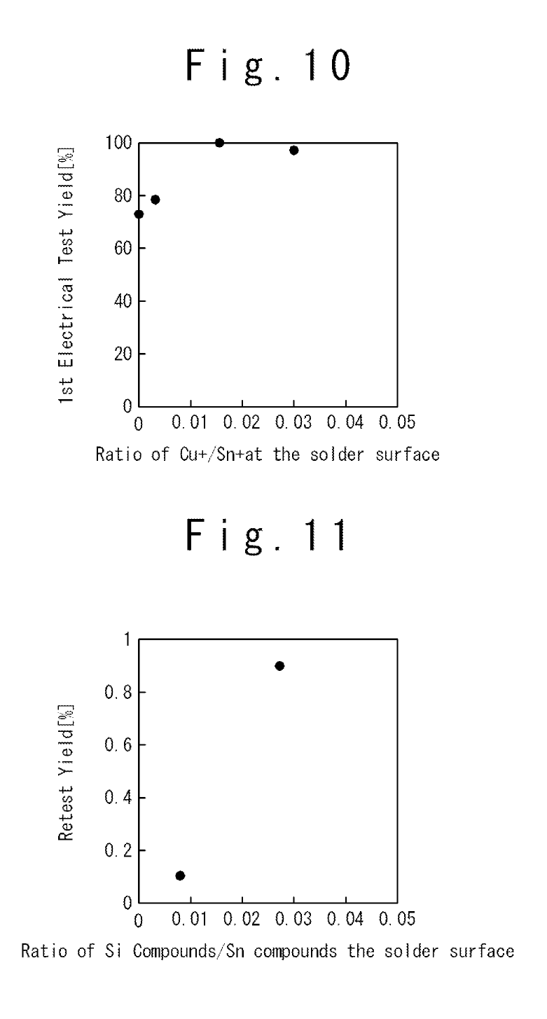

Subsequently, referencing to FIGS. 10 and 11, the effects of the present invention will be explained.

FIG. 10 shows a relationship between a quantity of Cu to Sn at the surface of the solder bump 7 and an yield rate of the semiconductor device 10. A horizontal axis of FIG. 10 shows a ratio of a number of Cu atoms to a number of Sn atoms in unit volume at the surface of the solder bump 7, wherein the ratio was measured by TOF-SIMS. A vertical axis of FIG. 10 shows an yield rate in continuity check of the electrical test of the solder bump 7. As shown in FIG. 10, when an amount of Cu existing on the surface of the solder bump 7 is increased, the semiconductor device 10 is easily judged to be a good item. Namely, it is shown that when the ratio of Cu to Sn at the surface of the solder bumps 7 is increased, conductivity in the surface part 23 is increased. As shown in FIG. 10, it is understood that when the ratio of the number of Cu atoms to the number of Sn atoms in a unit volume exceeds 0.01, the yield is remarkably increased. Furthermore, if the ratio of the number of atoms is more than 0.015, the yield becomes almost 100%.

In the present invention, the ratio of Cu atoms to Sn atoms in number in a unit volume at the surface part 23 can be more than 0.01, since the conductive metal such as Cu, Ni, Au, and Ag is linked to the amine in the soldering flux 5, the amine ligand is removed by water washing, the conductive metal is deposited, and the surface part 23 is formed. Especially, the ratio of the conductive metal atoms to Sn atoms can be more than 0.015 by increasing the contained amount of the amine.

Accordingly, the surface part 23 having high conductivity can be formed on the surface of the solder bump 7, and a contact resistance can be decreased between the solder bump 7 and the contact pin 11. As the results, at the continuity check, it becomes possible to remarkably suppress a possibility of faulty determining to be defective due to an electrical contacting failure between the contact pin 11 and the solder bump 7.

Meanwhile, a case of Cu is shown in FIG. 10, however, similar trends could be confirmed in cases of Ni, Au, and Ag. Namely, when a ratio of Ni or Au atoms to Sn atoms in number was more than 0.01, the yield was remarkably increased, and when the ratio is more than 0.015, the yield became almost 100%.

FIG. 11 shows a relationship between a ratio of an amount of Si to Sn at the surface of the solder bump 7 and the yield of the semiconductor device 10. A horizontal axis of FIG. 11 shows a ratio of a number of Si atoms to a number of Sn atoms in unit volume at the surface of the solder bump 7, wherein the ratio was measured by TOF-SIMS. A vertical axis of FIG. 11 shows a rate of which the semiconductor devices 10 once judged to be defects were judged to be good items in a retest. Namely, when a value of the vertical axis is large, it is shown that a possibility of judging good item to be a defect at a first continuity check is large. As shown in FIG. 11, when the ratio of Si atoms to Sn atoms in number in a unit volume is small, miss judgment is reduced. Specially, when the ratio of Si atoms to Sn atoms in number in a unit volume is smaller than 0.01, the miss judgment is remarkably reduced. Same trend was obtained in a case of using C instead of Si. As a material including Si and C formed on the surface of solder bump 7, insulating material derived from the solder resist 3, for example, an organic silicon compound, an acrylic compound, an epoxy compound, and a poly-dimethyl siloxane compound or the like are considered.

According to the present invention, since the solvent in the soldering flux 5 can melt and dissolve these insulating materials derived from the solder resist 3, miss judgment due to the material including Si or C compound can be suppressed.

In the above explanation, though the main component of the base material of the solder bump 7 was Sn compound, metals other than Sn may be used. Additionally, the base material of the solder bump 7 may be formed of Sn and metals other than Sn.

What is claimed is:

1. Soldering flux including:
a solvent of which solubility in water is more than 0.01% by weight and less than 6.8% by weight;
an organic acid component; and
an amine counteracting said organic acid component,
wherein solubility of said amine in water is more than 5.0% by weight, and said amine is able to be linked to a conductive metal via a coordination linkage.

2. The soldering flux according to claim 1, wherein said conductive metal component includes at least one of copper, nickel, silver, and gold.

3. The soldering flux according to claim 1, wherein said amine is adapted to be linked to said conductive metal such that said conductive metal is blended.

4. The soldering flux according to claim 3, wherein the conductive metal is blended in said amine by coordination linkage.

5. The soldering flux according to claim 1, wherein said amine includes at least one of ethylenediamine, polyoxyethylenediamine, a derivative of ethylenediamine, and a derivative of polyoxyethylenediamine.

6. The soldering flux according to claim 1, wherein said solvent includes a material selected from a group consisting of hexylglycol, 2-ethylhexylglycol, phenylglycol, phenyl-di-glycol, benzylglycol, butylpropyleneglycol, phenylpropyleneglycol, dibutyldiglycol, and propylpropyleneglycol.

7. The soldering flux according to claim 1, wherein a boiling point of said solvent is more than a melting point of the solder.

8. The soldering flux according to claim 1, wherein said organic acid component includes a plurality of organic acid group in one molecule.

9. The soldering flux according to claim 1, wherein said each organic acid group is a carboxyl group.

10. The soldering flux according to claim 1, wherein a melting point of said organic acid component is more than 145 degree.

11. A method of manufacturing a semiconductor device, comprising:
forming a solder bump by heating a solder bump together with soldering flux; and
washing said solder bump by water,
wherein said soldering flux includes:
a solvent of which solubility in water is more than 0.01% by weight and less than 6.8% by weight;
an organic acid component; and
an amine counteracting said organic acid component,
wherein solubility of said amine in water is more than 5.0% by weight, and said amine is able to be linked to a conductive metal via a coordination linkage.

12. The method according to claim 11, wherein said conductive metal component includes at least one of copper, nickel, silver, and gold.

13. The method according to claim 11, wherein said forming solder bump comprises:
applying said soldering flux on an electrode;
arranging said solder ball on said electrode after said applying; and
heating said solder ball such that said solder ball is melted to form said solder bump, after said arranging.

14. The method according to claim 11, wherein said amine is adapted to be linked to said conductive metal to blend said conductive metal component.

15. The method according to claim 11, wherein the conductive metal is blended in said amine by coordination linkage.

16. The method according to claim 11, wherein said solvent includes a material selected from a group consisting of hexylglycol, 2-ethylhexylglycol, phenylglycol, phenyl-di-glycol, benzylglycol, butylpropyleneglycol, phenylpropyleneglycol, dibutyldiglycol, and propylpropyleneglycol.

17. The method according to claim 11, wherein a boiling point of said solvent is more than a melting point of solder, and a melting point of said organic acid component is more than 145 degree.

18. The method according to claim 11, wherein said organic acid component includes a plurality of organic acid group in one molecule.

19. The method according to claim 11, wherein said amine includes at least one of ethylenediamine, polyoxyethylenediamine, a derivative of ethylenediamine, and a derivative of polyoxyethylenediamine.

20. The method according to claim 11, wherein said amine includes multidentate ligand having a plurality of group, and said plurality of group are linked to one conductive metal atom.
